(19) United States
(12) Patent Application Publication
(10) Pub. No.: US 2025/0089481 A1
(43) Pub. Date: Mar. 13, 2025

(54) DISPLAY DEVICE AND METHOD OF MANUFACTURING THE SAME

(71) Applicant: Samsung Display Co., LTD., Yongin-si (KR)

(72) Inventor: JAEKWON HWANG, Yongin-si (KR)

(21) Appl. No.: 18/810,931

(22) Filed: Aug. 21, 2024

(30) Foreign Application Priority Data
Sep. 13, 2023 (KR) 10-2023-0121935

(51) Int. Cl. H10K 59/127; H10K 50/115; H10K 59/12; H10K 59/122

(52) U.S. Cl. CPC H10K 59/1275; H10K 50/115; H10K 59/1201; H10K 59/122

(57) ABSTRACT

A display device includes: a first light emitting element disposed on a first surface of a first substrate and including a first light emitting layer including an organic light emitting material, a second light emitting element disposed on the first surface of the first substrate and including a second light emitting layer including an inorganic light emitting material, a second substrate facing the first surface of the first substrate and disposed on the first light emitting element and the second light emitting element, and a resin layer disposed on a second surface of the second substrate facing the first surface of the first substrate, including an active ingredient, spaced apart from the first light emitting element in a plan view, and overlapping the second light emitting element in the plan view.

This application claims priority to Korean Patent Application No. 10-2023-0121935, filed on Sep. 13, 2023, and all the benefits accruing therefrom under 35 U.S.C. § 119, the content of which in its entirety is herein incorporated by reference.

### BACKGROUND

### 1. Technical Field

The disclosure relates to a display device. More specifically the disclosure relates to a display device and a method of manufacturing the display device.

### 2. Description of the Related Art

As information technology develops, the importance of a display device as a connection medium between a user and information is being highlighted. For example, the use of display devices such as the like a liquid crystal display device (“LCD”), an organic light emitting display device (“OLED”), a plasma display device (“PDP”), a quantum dot display device is increasing.

Research is continuing on a display device with a hybrid structure that includes both an organic light emitting element and a quantum dot light emitting element. The quantum dot light emitting element has an advantage of high chromaticity, high luminous efficiency, and multi-coloring.

### SUMMARY

Embodiments provide a display device with improved element characteristics.

Embodiments provide a method for manufacturing the display device.

A display device according to an embodiment includes: a first light emitting element disposed on a first surface of a first substrate and including a first light emitting layer including an organic light emitting material, a second light emitting element disposed on the first surface of the first substrate and including a second light emitting layer including an inorganic light emitting material, a second substrate facing the first surface of the first substrate and disposed on the first light emitting element and the second light emitting element, and a resin layer disposed on a second surface of the second substrate facing the first surface of the first substrate, including an active ingredient, spaced apart from the first light emitting element in a plan view, and overlapping the second light emitting element in the plan view.

In an embodiment, the display device may further include a partition structure disposed between the first substrate and the second substrate and surrounding at least a portion of the resin layer.

In an embodiment, the display device may further include a pixel defining layer disposed on the first surface of the first substrate to surround the first light emitting layer and the second light emitting layer, and the partition structure may be disposed on the pixel defining layer

In an embodiment, at least a portion of the partition structure may be disposed between the first light emitting element and the second light emitting element in the plan view.

In an embodiment, the second light emitting element may include the active ingredient.

In an embodiment, the active ingredient included in the resin layer may include an acid.

In an embodiment, the inorganic light emitting material may include a quantum dot.

In an embodiment, a color of light emitted by the first light emitting element may be different from a color of light emitted by the second light emitting element.

In an embodiment, the display device may further include a common electrode on the first light emitting layer and the second light emitting layer, and the resin layer may be is spaced apart from the common electrode.

In an embodiment, the second substrate may be is spaced apart from the first substrate, the first light emitting element, and the second light emitting element.

A method of manufacturing a display device according to an embodiment includes: forming a first light emitting element and a second light emitting element on a first surface of a first substrate, wherein the first light emitting element includes a first light emitting layer including an organic light emitting material, and the second light emitting element includes a second light emitting layer including an inorganic light emitting material; forming a resin layer including an active ingredient on a second surface of a second substrate; and bonding the second substrate on which the resin layer is formed and the first substrate on which the first light emitting element and the second light emitting element are formed such that the resin layer is spaced apart from the first light emitting element and overlaps the second light emitting element in a plan view.

In an embodiment, after the bonding of the first substrate and the second substrate, the first surface of the first substrate and the second surface of the second substrate face each other, and the resin layer may be disposed between the first substrate and the second substrate after the bonding of the first substrate and the second substrate.

In an embodiment, the second light emitting layer may be formed of a quantum dot composition.

In an embodiment, the first light emitting element and the second light emitting element may be formed to emit light of different colors from each other.

In an embodiment, the active ingredient may include an acid.

In an embodiment, the forming of the resin layer on the second substrate may include: forming a preliminary resin layer including the active ingredient on the second surface of the second substrate, forming a photoresist pattern on the preliminary resin layer, and removing a portion of the preliminary resin layer using the photoresist pattern as a mask to form the resin layer.

In an embodiment, the method may further include: forming a partition structure defining an accommodation space on the first surface of the first substrate, and the forming of the partition structure may be performed before the bonding of the first substrate and the second substrate.

In an embodiment, after the bonding of the first substrate and the second substrate, the partition structure may be disposed between the first substrate and the second substrate, and the resin layer may be disposed in the accommodation space.

In an embodiment, the forming of the resin layer on the second substrate includes: forming a partition structure defining an accommodation space on the second surface of the second substrate, discharging a resin composition including the active ingredient into the accommodation space of the partition structure, and drying the resin composition to form the resin layer in the accommodation space.

In an embodiment, after the bonding of the first substrate and the second substrate, the partition structure may be disposed between the first substrate and the second substrate.

The display device according to embodiments of the present invention may be a display device with a hybrid structure that includes both an organic light emitting element and a quantum dot light emitting element. Additionally, the display device may include a resin layer containing an active ingredient. The active ingredient may promote a positive aging effect of the quantum dot light emitting element. On the other hand, when the active ingredient diffuses into the organic light emitting element, element characteristics may deteriorate, unlike the quantum dot light emitting element.

According to embodiments, the resin layer may selectively overlap the quantum dot light emitting element in a plan view, and may be spaced apart from the organic light emitting element in the plan view. Therefore, the active ingredient may selectively diffuse into the quantum dot light emitting element from the resin layer. That is, the active ingredient may not affect the organic light emitting element.

Additionally, the display device may further include a partition structure surrounding at least a portion of the resin layer. Accordingly, the active ingredient diffusing from the resin layer may be blocked from diffusing into a specific path by the partition structure. For example, the active ingredient may not reach the organic light emitting element due to the partition structure. Therefore, the active ingredient may not affect the organic light emitting element.

As a result, in the display device according to embodiments of the present invention, the active ingredient may be selectively diffused into the quantum dot light emitting element by the resin layer and the partition structure. That is, the active ingredient may not affect the organic light emitting element. Therefore, it is possible to promote the positive aging effect of the quantum dot light emitting element and at the same time prevent or reduce a deterioration of element characteristics of the organic light emitting element. Accordingly, element characteristics of the display device may be effectively improved.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment of the present invention.

FIG. 2 is a cross-sectional view taken along line I-I′ of FIG. 1.

FIG. 3 is a plan view illustrating an area A1 of FIG. 1.

FIG. 4 is a cross-sectional view taken along line II-II′ of FIG. 3.

FIG. 5 is a cross-sectional view schematically illustrating an example of the intermediate layer of FIG. 4.

FIG. 6 is a cross-sectional view schematically illustrating another example of the intermediate layer of FIG. 4.

FIGS. 7 to 14 are cross-sectional views illustrating a method of manufacturing a display device according to an embodiment of the present invention.

FIG. 15 is a cross-sectional view illustrating another example taken along line II-II′ of FIG. 3.

FIGS. 16 to 20 are cross-sectional views illustrating a method of manufacturing a display device according to an embodiment of the present invention.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

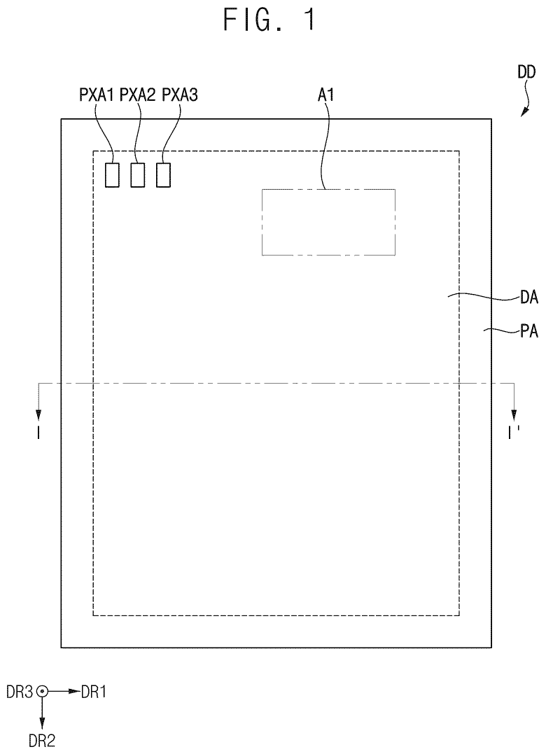

FIG. 1 is a plan view illustrating a display device according to an embodiment of the present invention.

Referring to FIG. 1, the display device DD according to an embodiment of the present invention may include a display area DA and a peripheral area PA. The display area DA may be an area that can display an image by generating light or adjusting a transmittance of light provided from an external light source. The peripheral area PA may be an area that does not display images. The peripheral area PA may be located around the display area DA. For example, the peripheral area PA may surround the entirety of the display area DA.

The display area DA may include a plurality of pixel areas. The pixel areas may be arranged in a matrix form on a plane defined by a first direction DR1 and a second direction DR2 intersecting the first direction DR1. For example, the pixel areas may include a first pixel area PXA1, a second pixel area PXA2, and a third pixel area PXA3.

The third direction DR3 may be a normal direction of the plane defined by the first direction DR1 and the second direction DR2. That is, the third direction DR3 may be perpendicular to both the first direction DR1 and the second direction DR2.

Each of the first pixel area PXA1, the second pixel area PXA2, and the third pixel area PXA3 may mean an area where light emitted from a light emitting element is emitted to the outside of the display device DD. In an embodiment, for example, the first pixel area PXA1 may emit a first light, the second pixel area PXA2 may emit a second light, and the third pixel area PXA3 may emit a third light. In an embodiment, the first light may be a blue light, the second light may be a red light, and the third light may be a green light. However, the present invention is not limited thereto. In an embodiment, for example, the first to third pixel areas PXA1, PXA2, and PXA3 may be combined to emit yellow, cyan, and magenta lights.

Each of the first pixel area PXA1, the second pixel area PXA2, and the third pixel area PXA3 may have a triangular planar shape, a square planar shape, a circular planar shape, an oval planar shape, or the like. In an embodiment, each of the first pixel area PXA1, the second pixel area PXA2, and the third pixel area PXA3 may have a rectangular planar shape. However, it is not necessarily limited to this, and each of the first pixel area PXA1, the second pixel area PXA2, and the third pixel area PXA3 may have a planar shape other than a rectangular shape.

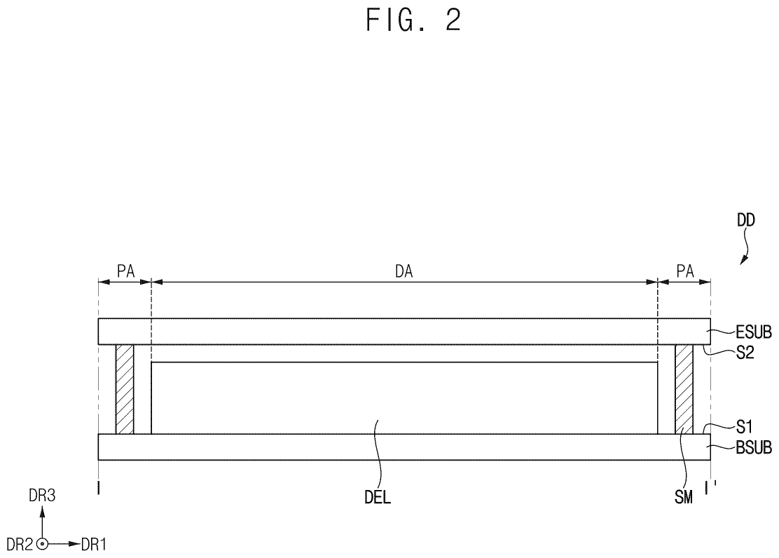

FIG. 2 is a cross-sectional view taken along line I-I′ of FIG. 1.

Referring to FIG. 2, the display device DD may include a first substrate BSUB, a display element layer DEL, a second substrate ESUB, and a sealing member SM.

The first substrate BSUB may serve as a base for the display device DD. In an embodiment, examples of materials that can be used as the first substrate BSUB may include glass, quartz, plastic, or the like. These can be used alone or in combination with each other.

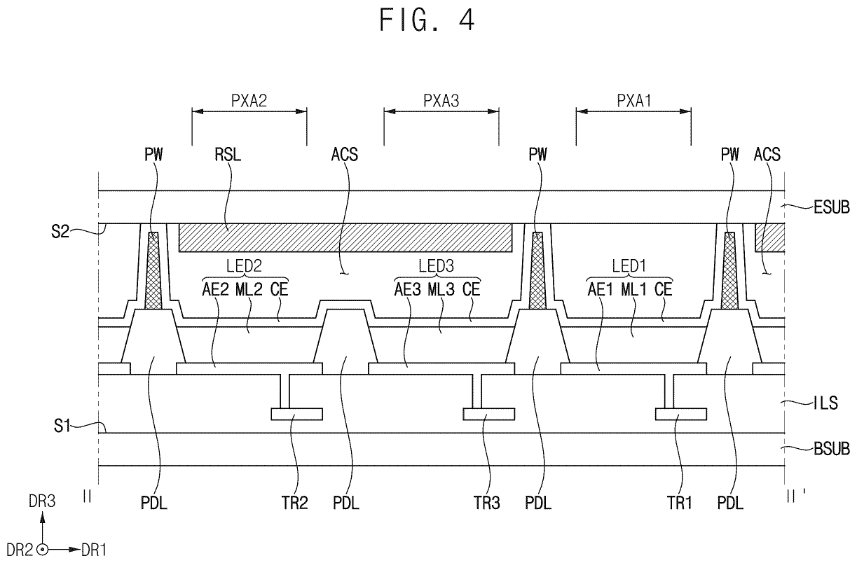

The display element layer DEL may be disposed on one surface (hereinafter referred to as a first surface S1) of the first substrate BUSB. The display element layer DEL may define the display area DA of the display device DD by playing a role in displaying an image. In other words, an area on the first substrate BSUB where the display element layer DEL is disposed may be the display area DA, and an area where the display element layer DEL is not disposed may be the peripheral area PA. That is, the display element layer DEL may overlap the display area DA in the third direction DR3 and may not overlap the peripheral area PA in the third direction DR3. A specific structure of the display element layer DEL will be described in more detail later with reference to FIG. 4.

The second substrate ESUB may be disposed on the display element layer DEL. The second substrate ESUB may be an encapsulation substrate that protects the display element layer DEL. In an embodiment, for example, the second substrate ESUB may include a glass.

The second substrate ESUB may face the first substrate BSUB. In other words, the second substrate ESUB may face the first surface S1 of the first substrate BSUB in the third direction DR3. That is, one surface of the second substrate ESUB (hereinafter referred to as a second surface S2) may face the first surface S1 of the first substrate BSUB.

The display area DA and peripheral area PA of the display device DD may also be applied to the first substrate BSUB and the second substrate ESUB. Specifically, an area overlapping the display element layer DEL in the third direction DR3 on the first substrate BSUB may be the display area DA of the first substrate BSUB, and an area not overlapping the display element layer DEL in the third direction DR3 on the first substrate BSUB may be the peripheral area PA of the first substrate BSUB. In addition, an area overlapping the display element layer DEL in the third direction DR3 on the second substrate ESUB may be the display area DA of the second substrate ESUB, and an area not overlapping the display element layer DEL in the third direction DR3 on the second substrate ESUB may be the peripheral area PA of the second substrate ESUB.

The sealing member SM surrounding edges of the first substrate BSUB and the second substrate ESUB may be disposed at the edges. The sealing member SM may bond the edge of the first substrate BSUB and the edge of the second substrate ESUB. Accordingly, the first substrate BUSB and the second substrate ESUB may be bonded. Specifically, the sealing member SM may be disposed at opposite ends of the first substrate BSUB in the first direction DR1 and opposite ends of the second substrate ESUB in the first direction DR1 with respect to FIG. 2, and thereby opposite ends of the first substrate BSUB and the second substrate ESUB in the first direction DR1 may be bonded. Accordingly, the first substrate BSUB and the second substrate ESUB are spaced apart from each other (i.e., in does not directly contact with each other) in the third direction DR3 in the display area DA, and the first substrate BSUB and the second substrate ESUB may be bonded by the sealing member SM at opposite ends of the peripheral area PA in the first direction DR1.

The sealing member SM may not overlap the display area DA and may overlap the peripheral area PA in the plan view. Specifically, the sealing member SM may be spaced apart from the display device layer DEL on the opposite sides of the first direction DR1 with reference to FIG. 2. In other words, the sealing member SM may be arranged to surround an outer edge of the display element layer DEL.

In an embodiment, the sealing member SM may bond the first substrate BSUB and the second substrate ESUB through a laser irradiation process, a UV irradiation process, etc. in a manufacturing process of the display device DD to be described later. In an embodiment, for example, the sealing member SM may include glass.

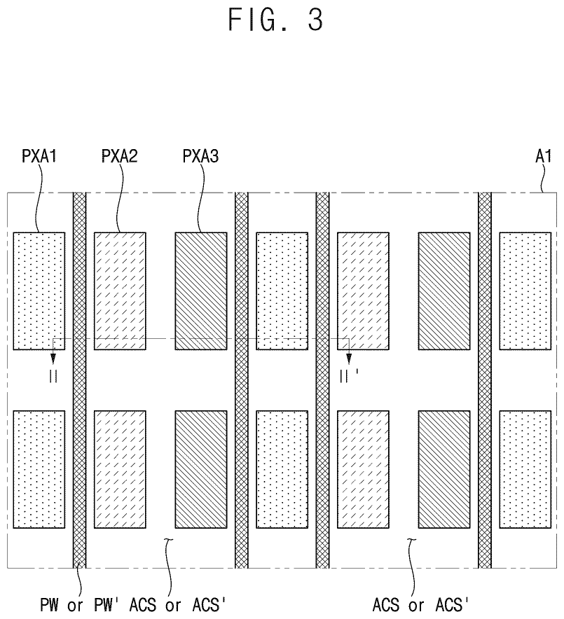

FIG. 3 is a plan view illustrating an area A1 of FIG. 1, and FIG. 4 is a cross-sectional view taken along line II-II′ of FIG. 3. For convenience of description, FIG. 3 illustrates only an arrangement of the pixel areas PXA1, PXA2, and PXA3 and a partition structure PW in the area A1 of FIG. 1. As used herein, the “plan view” is a view in a thickness direction (i.e., the third direction DR3) of the first substrate BSUB.

Referring to FIGS. 1, 3, and 4, the display device DD may include the first substrate BSUB, first to third driving elements TR1, TR2, TR3, an insulating structure ILS, light emitting elements LED1, LED2, LED3, a pixel defining layer PDL, the partition structure PW, a resin layer RSL, and the second substrate ESUB.

As described above, the first substrate BUSB and the second substrate ESUB may face each other in the third direction DR3, and the first to third driving elements TR1, TR2, TR3, the insulating structure ILS, the first to third light emitting elements LED1, LED2, LED3, the pixel defining layer PDL, the partition structure PW, and the resin layer RSL may be disposed between the first substrate BSUB and the second substrate ESUB.

Here, the first light emitting element LED1 may include a first pixel electrode AE1, a first intermediate layer ML1, and a common electrode CE, and the second light emitting element LED2 may include a second pixel electrode AE2, a second intermediate layer ML2, and the common electrode CE, and the third light emitting element LED3 may include a third pixel electrode AE3, a third intermediate layer ML3, and the common electrode CE.

The first to third driving elements TR1, TR2, TR3, the insulating structure ILS, the first to third light emitting elements LED1, LED2, LED3, and the pixel defining layer PDL may be components included in the display element layer DEL of FIG. 2.

The first to third driving elements TR1, TR2, TR3 may be disposed in the display area DA on the first substrate BSUB. Each of the first to third driving elements TR1, TR2, TR3 may include at least one transistor. A channel layer of the transistor may include an oxide semiconductor, a silicon semiconductor, an organic semiconductor, or the like.

The insulating structure ILS may cover the first to third driving elements TR1, TR2, TR3. The insulating structure ILS may include at least one inorganic insulating layer and at least one organic insulating layer.

The first to third pixel electrodes AE1, AE2, AE3 may be disposed on the insulating structure ILS. Each of the first to third pixel electrodes AE1, AE2, AE3 may include a conductive material such as a metal, alloy, conductive metal nitride, conductive metal oxide, or transparent conductive material. Each of the first to third pixel electrodes AE1, AE2, AE3 may have a single-layer structure or a multi-layer structure including a plurality of conductive layers. In an embodiment, for example, the first pixel electrode AE1 may be arranged to correspond to the first pixel area PXA1, the second pixel electrode AE2 may be arranged to correspond to the second pixel area PXA2, and the third pixel electrode AE3 may be arranged to correspond to the third pixel area PXA3.

The first to third pixel electrodes AE1, AE2, AE3 may be electrically connected to the first to third driving elements TR1, TR2, TR3, respectively, through contact holes defined in the insulating structure ILS.

The pixel defining layer PDL may be disposed on the first to third pixel electrodes AE1, AE2, AE3. The pixel defining layer PDL may include an organic insulating material. Examples of the organic insulating material may include photoresist, polyacryl-based resin, polyimide-based resin, polyamide-based resin, siloxane-based resin, acryl-based resin, epoxy-based resin, or the like. These can be used alone or in combination with each other. The pixel defining layer PDL may define a pixel opening that exposes at least a portion of each of the first to third pixel electrodes AE1, AE2, AE3.

The first to third intermediate layers ML1, ML2, ML3 may be disposed on the first to third pixel electrodes AE1, AE2, AE3 exposed by the pixel opening of the pixel defining layer PDL. Specifically, the first intermediate layer ML1 may be disposed on the first pixel electrode AE1, the second intermediate layer ML2 may be disposed on the second pixel electrode AE2, and the third intermediate layer ML3 may be disposed on the third pixel electrode AE3. In other words, the first intermediate layer ML1 may be arranged to correspond to the first pixel area PXA1, the second intermediate layer ML2 may be arranged to correspond to the second pixel area PXA2, and the third intermediate layer ML3 may be arranged to correspond to the third pixel area PXA3.

The first intermediate layer ML1 may include a material that emits the first light, the second intermediate layer ML2 may include a material that emits the second light, and the third intermediate layer ML3 may include a material that emits the third light. As described above, the first light may be a blue light, the second light may be a red light, and the third light may be a green light. However, the present invention is not necessarily limited thereto.

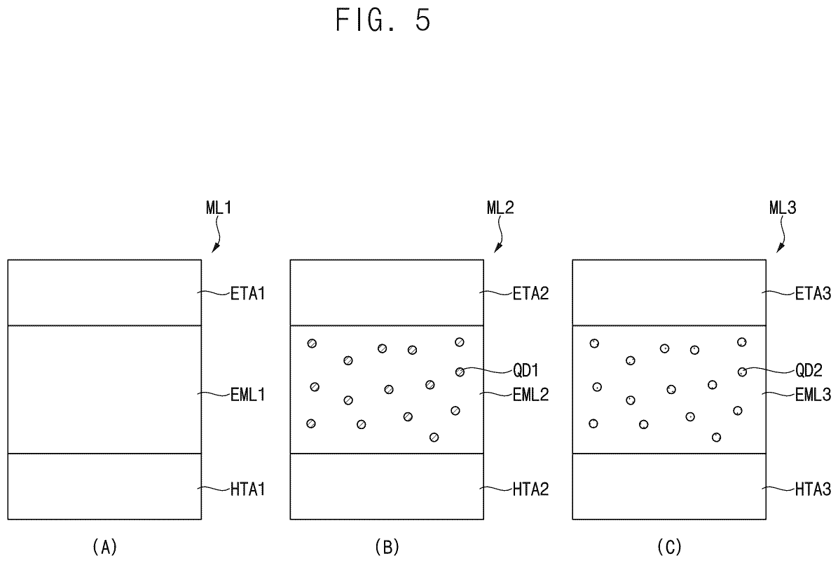

FIG. 5 is a cross-sectional view schematically illustrating an example of the intermediate layer of FIG. 4.

Referring further to FIG. 5, as illustrated in (A) of FIG. 5, the first intermediate layer ML1 may include a first hole transport area HTA1, a first light emitting layer EML1, and a first electron transport area ETA1 stacked sequentially. In addition, as illustrated in (B) of FIG. 5, the second intermediate layer ML2 may include a second hole transport area HTA2, a second light emitting layer EML2, and a second electron transport area ETA2 stacked sequentially. In addition, as illustrated in (C) of FIG. 5, the third intermediate layer ML3 may include a third hole transport area HTA3, a third light emitting layer EML3, and a third electron transport area ETA3 stacked sequentially.

In this case, each of the first to third light emitting elements LED1, LED2, LED3 may be a conventional type light emitting element in which each of the first to third pixel electrodes AE1, AE2, AE3 is an anode and the common electrode CE is a cathode.

In an embodiment, the first hole transport area HTA1, the second hole transport area HTA2, and the third hole transport area HTA3 may be separated from each other. However, the present invention is not necessarily limited thereto, and in another embodiment, the first hole transport area HTA1, the second hole transport area HTA2, and the third hole transport area HTA3 may be connected to each other. That is, the first intermediate layer ML1, the second intermediate layer ML2, and the third intermediate layer ML3 may share one hole transport area.

Likewise, in an embodiment, the first electron transport area ETA1, the second electron transport area ETA2, and the third hole transport area ETA3 may be separated from each other. However, the present invention is not necessarily limited thereto, and in another embodiment, the first electron transport area ETA1, the second electron transport area ETA2, and the third hole transport area ETA3 may be connected to each other. That is, the first intermediate layer ML1, the second intermediate layer ML2, and the third intermediate layer ML3 may share one electron transport area.

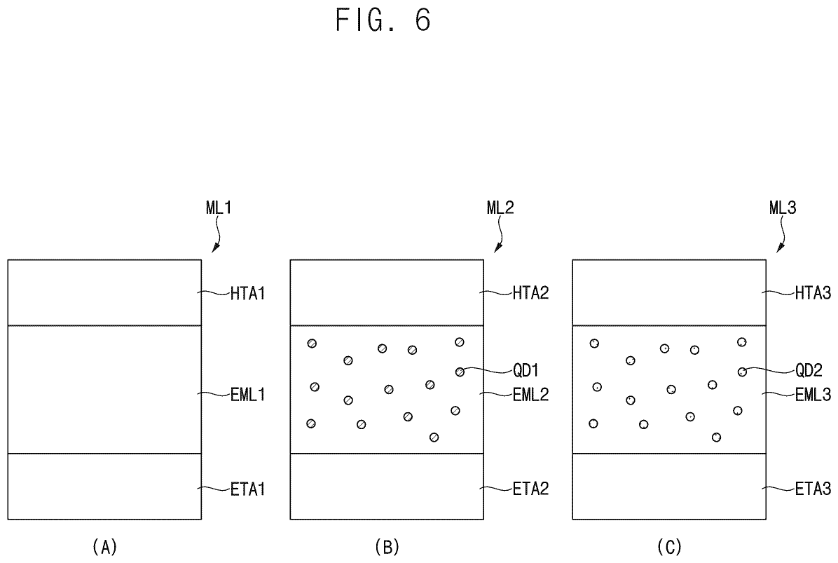

FIG. 6 is a cross-sectional view schematically illustrating another example of the intermediate layer of FIG. 4.

Referring further to FIG. 6, as illustrated in (A) of FIG. 6, the first intermediate layer ML1 may include the first electron transport area ETA1, the first light emitting layer EML1, and the first hole transport area HTA1 stacked sequentially. In addition, as illustrated in (B) of FIG. 6, the second intermediate layer ML2 may include the second electron transport area ETA2, the second light emitting layer EML2, and the second hole transport area HTA2 stacked sequentially. In addition, as illustrated in (C) of FIG. 6, the third intermediate layer ML3 may include the third electron transport area ETA3, the third light emitting layer EML3, and the third hole transport area HTA3 stacked sequentially.

In this case, each of the first to third light emitting elements LED1, LED2, LED3 may be an inverted type light emitting element in which each of the first to third pixel electrodes AE1, AE2, AE3 is a cathode and the common electrode CE is an anode.

Similar to the description with reference to FIG. 5, in a case of the inverted type light emitting element, the first hole transport area HTA1, the second hole transport area HTA2, and the third hole transport area HTA3 may be separated from or connected to each other. Additionally, the first electron transport area ETA1, the second electron transport area ETA2, and the third hole transport area ETA3 may be separated from or connected to each other.

Hereinafter, with reference to FIGS. 5 and 6, a structure of each of the first to third intermediate layers ML1, ML2, ML3 will be described in more detail.

The first to third hole transport areas HTA1, HTA2, HTA3 may have i) a single layer structure formed of a single layer of a single material, ii) a single layer structure formed of a single layer of a plurality of different materials, or iii) a multi-layer structure having a plurality of layers of a plurality of different materials.

Each of the first to third hole transport areas HTA1, HTA2, HTA3 may include at least one layer of a hole injection layer, a hole transport layer, a light emission auxiliary layer, and an electron blocking layer.

In an embodiment, for example, each of the first to third hole transport areas HTA1, HTA2, HTA3 may have a single layer structure formed of a single layer of a plurality of different materials, or a multi-layer structure of hole injection layer/hole transport layer, hole injection layer/hole transport layer/light emission auxiliary layer, hole injection layer/light emission auxiliary layer, hole transport layer/light emission auxiliary layer, or hole injection layer/hole transport layer/electron blocking layer sequentially stacked on the first to third pixel electrodes AE1, AE2, AE3. However, the present invention is not necessarily limited thereto.

Each of the first to third hole transport areas HTA1, HTA2, HTA3 may include an amorphous inorganic or organic material. The light emission auxiliary layer may increase light emission efficiency by compensating for an optical resonance distance according to wavelength of light emitted from the first to third light emitting layers EML1, EML2, EML3, and the electron blocking layer may prevent electron injection from the first to third electron transport areas ETA1, ETA2, ETA3.

The first to third light emitting layer EML1, EML2, EML3 may include a material which emits light. In an embodiment, for example, the first light emitting layer EML1 may include a material that emits the first light, the second light emitting layer EML2 may include a material that emits the second light, and the third light emitting layer EML3 may include a material that emits the third light. In an embodiment, the first light may be a blue light, the second light may be a red light, and the third light may be a green light. However, the present invention is not limited to this.

Specifically, the first light emitting layer EML1 may include an organic light emitting material. That is, the first light emitting element LED1 may be an organic light emitting element. The organic light emitting material may include a low molecular weight organic compound or a high molecular weight organic compound. Examples of the low molecular weight organic compound may include copper phthalocyanine, diphenylbenzidine (N,N-diphenylbenzidine), tris-(8-hydroxyquinoline)aluminum, or the like. Examples of the high molecular weight organic compound may include poly(3,4-ethylenedioxythiophene), polyaniline, poly-phenylenevinylene, polyfluorene, or the like. These can be used alone or in combination with each other.

The second light emitting layer EML2 may include an inorganic light emitting material. In an embodiment, for example, the inorganic light emitting material included in the second light emitting layer EML2 may include a first quantum dot QDR1. That is, the second light emitting element LED2 may be a quantum dot light emitting element. The third light emitting layer EML3 may include an inorganic light emitting material. In an embodiment, for example, the inorganic light emitting material included in the third light emitting layer EML3 may include a second quantum dot QDR2. That is, the third light emitting element LED3 may be a quantum dot light emitting element. As a result, the display device DD may have a hybrid structure that includes both an organic light emitting element and a quantum dot light emitting element.

The first quantum dot QD1 and the second quantum dot QD2 may emit light when stimulated by light. In an embodiment, for example, each of the first quantum dot QD1 and the second quantum dot QD2 may include a group II-VI semiconductor compound, a group III-VI semiconductor compound, a group III-V semiconductor compound, a group IV-VI semiconductor compound, a group IV element or compound, a group I-III-VI semiconductor compound, or the like. These can be used alone or in combination with each other.

Examples of the II-VI group semiconductor compound may include binary compounds such as CdS, CdSe, CdTe, ZnS, ZnSe, ZnTe, ZnO, HgS, HgSe, HgTe, MgS, MgSe, etc.; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe MgZnS, MgZnSe, etc.; quaternary compounds such as CdZnSeS, CdZnSeTe, CdZnSTe, CdHgSeS, CdHgSeTe, CdHgSTe, HgZnSeS, HgZnSeTe, HgZnSTe, etc.; or any combination thereof.

Examples of the III-VI group semiconductor compound may include binary compounds such as In₂S₃, Ga₂S₃, etc.; ternary compounds such as InGaS₃, InGaSe₃, etc.; or any combination thereof.

Examples of the group III-V semiconductor compound may include binary compounds such as GaN, GaP, GaAs, GaSb, AlN, AlP, AlAs, AlSb, InN, InP, InAs, InSb, etc.; ternary compounds such as GaNP, GaNAs, GaNSb, GaPAs, GaPSb, AlNP, AlNAs, AlNSb, AlPAs, AlPSb, InAsP, InGaP, InGaAs, InAlP, InNP, InNAs, InNSb, InPAs, InPSb, GaAlNP, etc.; quaternary compounds such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, etc.; or any combination thereof. The group III-V semiconductor compound may further include a group II metal (e.g., InZnP).

Examples of the IV-VI group semiconductor compound may include binary compounds such as SnS, SnSe, SnTe, PbS, PbSe, PbTe, etc.; ternary compounds such as SnSeS, SnSeTe, SnSTe, PbSeS, PbSeTe, PbSTe, SnPbS, SnPbSe, SnPbTe, etc.; quaternary compounds such as SnPbSSe, SnPbSeTe, SnPbSTe, etc.; or any combination thereof.

Examples of the group IV element or compound may include Si and/or Ge; binary compounds such as SiC, SiGe, etc.; or any combination thereof.

Examples of the Group I-III-VI semiconductor compound may include ternary compounds such as AgInS, AgInS₂, CuInS, CuInS₂, CuGaO₂, AgGaO₂, AgAlO₂, etc.; or any combination thereof. The Group I-III-VI semiconductor compound may further include a Group II element. In an embodiment, for example, the group I-III-VI semiconductor compound may include a quaternary element compound such as CuInZnS.

Each of the first quantum dot QD1 and the second quantum dot QD2 may have a single structure with homogeneous components and composition, or a complex structure such as a core-shell structure, a gradient structure, or the like.

Each of the first to third electron transport areas ETA1, ETA2, ETA3 may have i) a single layer structure formed of a single layer of a single material, ii) a single layer structure formed of a single layer of a plurality of different materials, or iii) a multi-layer structure having a plurality of layers of a plurality of different materials.

Each of the first to third electron transport areas ETA1, ETA2, ETA3 may include at least one layer of a buffer layer, a hole blocking layer, an electron control layer, an electron transport layer, and an electron injection layer, but the present invention is not necessarily limited thereto.

Additionally, each of the first to third electron transport areas ETA1, ETA2, ETA3 may include an amorphous inorganic or organic material

Referring to FIGS. 1, 3, and 4 again, the partition structure PW may be disposed on the pixel defining layer PDL.

The partition structure PW may not overlap with the first to third pixel areas PXA1, PXA2, PXA3 in the third direction DR3. That is, the partition structure PW may be spaced apart from the first to third pixel areas PXA1, PXA2, PXA3 in a plan view. Specifically, the partition structure PW may be spaced apart from the first to third intermediate layers ML1, ML2, ML3 in the plan view. In other words, the partition structure PW may be spaced apart from the first to third light emitting layers EML1, EML2, EML3 (see in FIGS. 5 and 6) in the plan view.

As illustrated in FIG. 3, at least a portion of the partition structure PW may be disposed between the first pixel area PXA1 and the second pixel area PXA2 and between the first pixel area PXA1 and the third pixel area PXA3. In an embodiment, for example, the partition structure PW may surround the second pixel area PXA2 and the third pixel area PXA3 in the plan view.

In other words, in the plan view, at least a portion of the partition structure PW may be disposed between the first light emitting element LED1 and the second light emitting element LED and between the first light emitting element LED1 and the third light emitting element LED3. In an embodiment, for example, the partition structure PW may surround the second light emitting element LED2 and the third light emitting element LED3 in the plan view.

The partition structure PW may define an accommodation space ACS that overlaps the second pixel area PXA2 and the third pixel area PXA3 in the third direction DR3. At this time, the accommodation space ACS of the partition structure PW may not overlap with the first pixel area PXA1 in the third direction DR3.

That is, the accommodation space ACS of the partition structure PW may be a space defined by an inner surface of the partition structure PW surrounding the second pixel area PXA2 and the third pixel area PXA3 in the plan view. In an embodiment, for example, the partition structure PW may mean a space for arranging the resin layer RSL. This will be described in more detail later.

As a result, the accommodation space ACS of the partition structure PW may overlap the second light emitting element LED2 and the third light emitting element LED3 in the plan view, and may be spaced apart from the first light emitting element LED1 in the plan view. Specifically, the accommodation space ACS of the partition structure PW may overlap the second intermediate layer ML2 and the third intermediate layer ML3 in the plan view, and may be spaced apart from the first intermediate layer ML1 in the plan view. In an embodiment, for example, the accommodation space ACS of the partition structure PW may overlap the second light emitting layer EML2 (see in FIGS. 5 and 6) and the third light emitting layer EML3 (see in FIGS. 5 and 6) in the plan view, and may be spaced apart from the first light emitting layer EML1 (see in FIGS. 5 and 6) in the plan view.

In an embodiment, the partition structure PW may include an organic insulating material. Examples of the organic insulating materials that can be used as the partition structure PW may include photoresist, polyacryl-based resin, polyimide-based resin, polyamide-based resin, siloxane-based resin, acryl-based resin, epoxy-based resin, or the like. These can be used alone or in combination with each other.

In FIGS. 3 and 4, the partition structure PW has been described as a separate structure that is stacked on the pixel defining layer PDL and defines an interface with the pixel defining layer PDL, but the present invention is not necessarily limited thereto. In an embodiment, for example, the partition structure PW may be formed integrally with the pixel defining layer PDL by using the same material.

In addition, a planar shape of the partition structure PW illustrated in FIG. 3 and a cross-sectional shape of the partition structure PW illustrated in FIG. 4 are only examples, and the present invention is not necessarily limited thereto. In an embodiment, for example, a shape of the partition structure PW may vary depending on a planar shape of each of the pixel areas PXA1, PXA2, PXA3, an arrangement of the pixel areas PXA1, PXA2, PXA3, or the like.

The common electrode CE may be disposed on the pixel defining layer PDL, the first to third intermediate layers ML1, ML2, ML3, and the partition structure PW. The common electrode CE may include a conductive material such as a metal, alloy, conductive metal nitride, conductive metal oxide, or transparent conductive material. In an embodiment, the common electrode CE may continuously extend across a plurality of pixel areas.

As a result, the first light emitting element LED1 including the first pixel electrode AE1, the first intermediate layer ML1, and the common electrode CE may be an organic light emitting element that emits the first light. Additionally, the second light emitting element LED2 including the second pixel electrode AE2, the second intermediate layer ML2, and the common electrode CE may be a quantum dot light emitting element that emits the second light. Additionally, the third light emitting element LED3 including the third pixel electrode AE3, the third intermediate layer ML3, and the common electrode CE may be a quantum dot light emitting element that emits the third light. In an embodiment, the first light may be a blue light, the second light may be a red light, and the third light may be a green light. However, the present invention is not limited thereto.

The resin layer RSL may be disposed on the second surface S2 of the second substrate ESUB. The resin layer RSL may overlap the second light emitting element LED2 and the third light emitting element LED3 in the plan view, and may be spaced apart from the first light emitting element LED1 in the plan view. In other words, the resin layer RSL may selectively overlap a quantum dot light emitting element and be spaced apart from an organic light emitting element in the plan view.

Specifically, the resin layer RSL may overlap the second intermediate layer ML2 and the third intermediate layer ML3 in the plan view, and may be spaced apart from the first intermediate layer ML1 in the plan view. That is, the resin layer RSL may overlap the second light emitting layer EML2 (see in FIGS. 5 and 6) and the third light emitting layer EML3 (see in FIGS. 5 and 6) in the plan view, and may be spaced apart from the first light emitting layer EML1 (see in FIGS. 5 and 6).

In an embodiment, for example, the resin layer RSL may be disposed in the accommodation space ACS of the partition structure PW. Accordingly, at least a portion of the resin layer RSL may be surrounded by the partition structure PW in the plan view. In an embodiment, for example, the entirety of the resin layer RSL may be surrounded by the partition structure PW in the plan view.

The resin layer RSL may include a resin and an active ingredient. Examples of the resin that can be used as the resin layer RSL may include photoresist, polyacryl-based resin, polyimide-based resin, polyamide-based resin, siloxane-based resin, acryl-based resin, epoxy-based resin, or the like. These can be used alone or in combination with each other.

The active ingredient may include an acid. In an embodiment, for example, the active ingredient may include acrylic acid, citric acid, iso-butyric acid, carboxylic acid, or the like. These can be used alone or in combination with each other.

The active ingredient of the resin layer RSL may diffuse into the second light emitting element LED2 and the third light emitting element LED3. That is, the second light emitting element LED2 and the third light emitting element LED3 may include the active ingredient diffused from the resin layer RSL. The active ingredient may promote a positive aging effect of the second light emitting element LED2 and the third light emitting element LED3, which are quantum dot light emitting elements.

In a display device with a hybrid structure that includes both a quantum dot light emitting element and an organic light emitting element, when the active ingredient diffuses into an organic light emitting element, element characteristics may deteriorate, unlike quantum dot light emitting elements.

According to embodiments, the resin layer RSL may selectively overlap the second light emitting element LED2 and the third light emitting element LED3 in the plan view, and may be spaced apart from the first light emitting element LED1 in the plan view. That is, the resin layer RSL may selectively overlap a quantum dot light emitting device in the plan view and be spaced apart from an organic light emitting element in the plan view. Accordingly, the active ingredient may be selectively diffused into the second light emitting element LED2 and the third light emitting element LED3, which are the quantum dot light emitting elements from the resin layer RSL. That is, the active ingredient may not affect the first light emitting element LED1, which is an organic light emitting element.

Additionally, the active ingredient diffusing from the resin layer RSL may be blocked from diffusing into a specific path by the partition structure PW. In an embodiment, for example, the active ingredient may not reach the first light emitting element LED1, which is an organic light emitting element, due to the partition structure PW. Accordingly, the active ingredient may not affect the first light emitting element LED1.

As a result, the active ingredient may be selectively diffused into the second light emitting element LED2 and the third light emitting element LED3, which are quantum dot light emitting elements, by the resin layer RSL and the partition structure PW. That is, the active ingredient may not affect the first light emitting element LED1, which is an organic light emitting element. Therefore, it is possible to promote the positive aging effect of a quantum dot light emitting element and at the same time prevent or reduce a deterioration of element characteristics of an organic light emitting element. Accordingly, element characteristics of the display device DD may be effectively improved.

In an embodiment, the resin layer RSL may be spaced apart from the common electrode CE. That is, the resin layer RSL may not directly contact with (i.e., spaced apart from) the common electrode CE. Accordingly, a phenomenon in which the active ingredient of the resin layer RSL reaches the first light emitting element LED1 through the common electrode CE may be prevented or reduced. Accordingly, element characteristics of the display device DD may be further improved.

It has been described that two of the first to third light emitting elements LED1, LED2, LED3 (for example, the second and third light emitting elements LED2, LED3) are a quantum dot light emitting element, respectively, and the remaining one (for example, the first light emitting element LED1) is an organic light emitting element, but the present invention is not necessarily limited thereto.

In an embodiment, for example, in an embodiment, one of the first to third light emitting elements LED1, LED2, LED3 may be a quantum dot light emitting element, and the remaining two light emitting elements may be an organic light emitting element respectively. In this case, the resin layer RSL may selectively overlap the one light emitting element, which is a quantum dot light emitting, in the plan view, and be spaced apart from the remaining two light emitting elements, which are a quantum dot light emitting, in the plan view. That is, the partition structure PW may define an accommodation space that selectively overlaps the one light emitting element in the plan view.

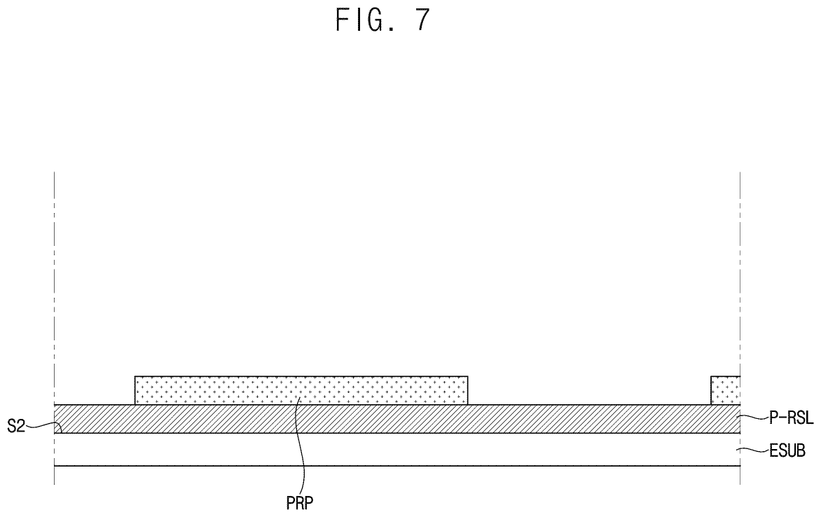

FIGS. 7 to 14 are cross-sectional views illustrating a method of manufacturing a display device according to an embodiment of the present invention.

Specifically, FIGS. 7 to 14 are cross-sectional views for illustrating a manufacturing method of the display device described with reference to FIG. 4.

Referring to FIG. 7, a preliminary resin layer P-RSL may be formed on the second surface S2 of the second substrate ESUB. The preliminary resin layer P-RSL may be formed by applying a composition for forming the preliminary resin layer P-RSL on the second surface S2 of the second substrate ESUB. In an embodiment, for example, the composition for forming the preliminary resin layer P-RSL may include the resin, a solvent, and the active ingredient. That is, the preliminary resin layer P-RSL may include the resin and the active ingredient.

Afterwards, a photo resist pattern PRP may be formed on the preliminary resin layer P-RSL. The photoresist pattern PRP may cover at least a portion of the preliminary resin layer P-RSL and may expose at least the other portion of the preliminary resin layer P-RSL. In an embodiment, the photoresist pattern PRP may be formed by applying a photoresist layer on the preliminary resin layer P-RSL and then exposing and developing the photoresist layer using an exposure mask or the like.

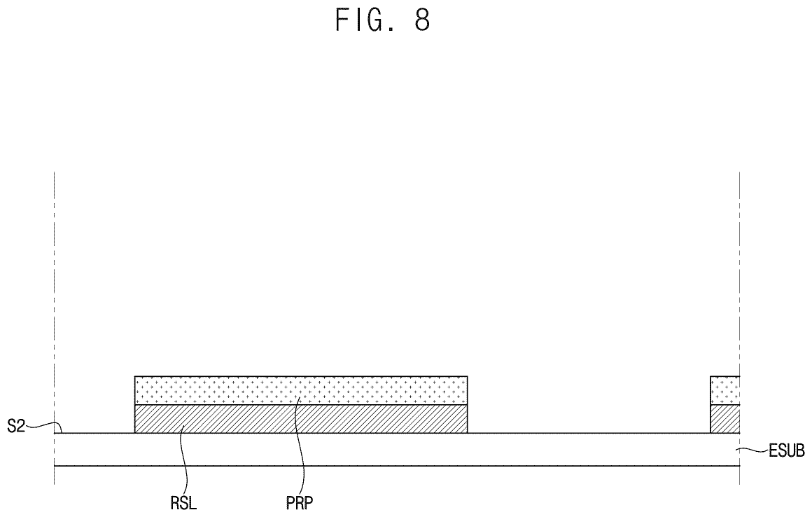

Referring further to FIG. 8, a portion of the preliminary resin layer P-RSL may be removed using the photo resist pattern PRP as a mask. That is, the portion of the preliminary resin layer P-RSL exposed from the photoresist pattern PRP may be removed. A portion of the preliminary resin layer P-RSL covered by the photoresist pattern PRP may remain, and thus, the resin layer RSL may be formed. Therefore, the resin layer RSL may include the active ingredient. In an embodiment, for example, a process of removing the portion of the preliminary resin layer P-RSL may be performed through an etching process, exposure and development process, or the like.

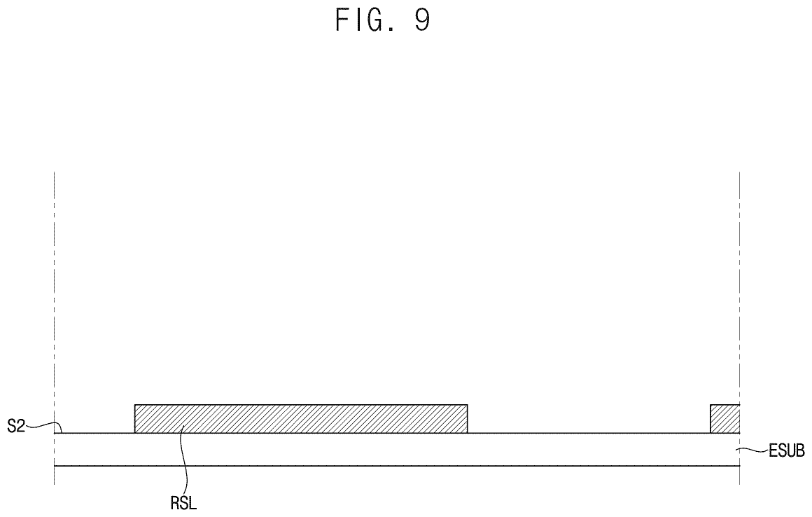

Thereafter, with further reference to FIG. 9, the photo resist pattern PRP may be removed. In an embodiment, for example, the photoresist pattern PRP may be removed through a strip process or the like.

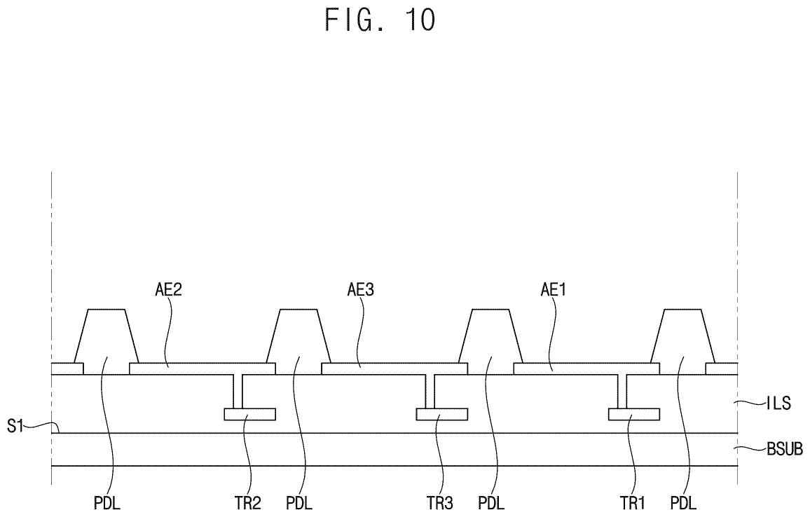

Referring to FIG. 10, the first to third driving elements TR1, TR2, TR3, the insulating structure ILS, and the first to third pixel electrodes AE1, AE2, AE3 and the pixel defining layer PDL may be formed on the first surface S1 of the first substrate BSUB.

In an embodiment, for example, the first to third driving elements TR1, TR2, TR3 may be formed by applying conductive layers on the first substrate BSUB and performing a process of patterning the conductive layers multiple times.

Additionally, the insulating structure ILS may be formed by applying insulating layers on the first substrate BUSB and performing a process of patterning the insulating layers multiple times.

Additionally, the first to third pixel electrodes AE1, AE2, AE3 may be formed through a process of applying a conductive layer on the insulating structure ILS and patterning the conductive layer.

Additionally, the pixel defining layer PDL may be formed through a process of applying an insulating layer on the insulating structure ILS and the first to third pixel electrodes AE1, AE2, AE3 and patterning the insulating layer. The pixel defining layer PDL may be formed to define the pixel opening exposing at least a portion of each of the first to third pixel electrodes AE1, AE2, AE3. In an embodiment, the pixel defining layer PDL may be formed of an organic insulating material.

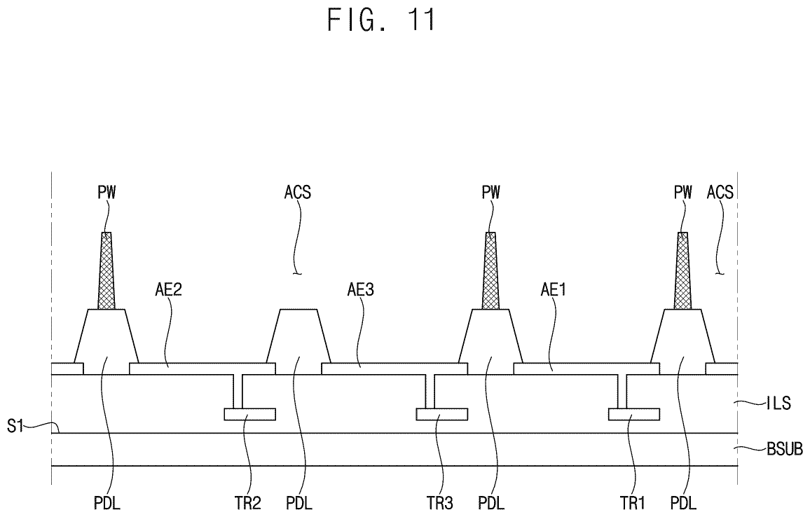

Thereafter, referring to FIG. 11, the partition structure PW may be formed on the pixel defining layer PDL. The partition structure PW may be formed through a process of applying an insulating layer on the first to third pixel electrodes AE1, AE2, AE3 and the pixel defining layer PDL, and patterning the insulating layer. The partition structure PW may be formed to define the accommodation space ACS that overlaps with the pixel opening exposing at least a portion of the second pixel electrode AE2 and the pixel opening exposing at least a portion of the third pixel electrode AE3 in the plan view. In an embodiment, the partition structure PW may be formed of an organic insulating material.

With reference to FIGS. 10 and 11, it has been described that the pixel defining layer PDL and the partition structure PW are formed through separate processes, but the present invention is not necessarily limited thereto. In an embodiment, the pixel defining layer PDL and the partition structure PW may be formed integrally through the same process. In an embodiment, for example, the pixel defining layer PDL and the partition structure PW may be formed simultaneously through a process of applying an insulating layer on the insulating structure ILS and the first to third pixel electrodes AE1, AE2, AE3 and exposing and developing the insulating layer using a halftone mask, or the like.

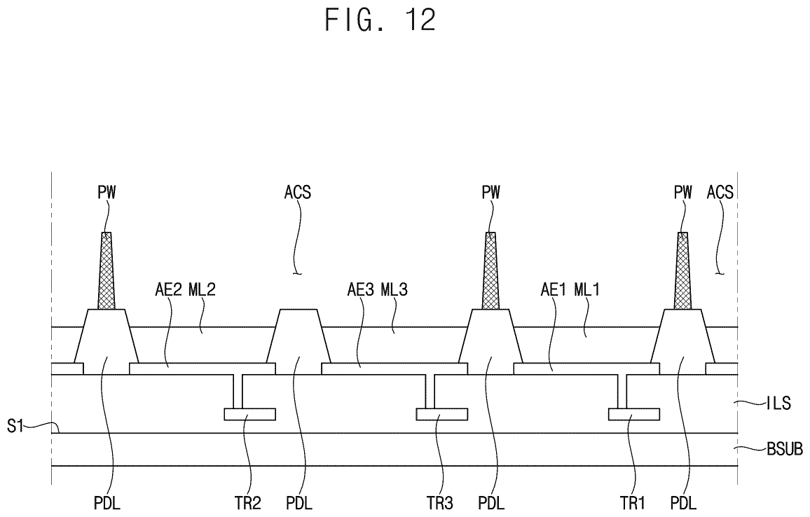

Referring to FIG. 12, the first to third intermediate layers ML1, ML2, ML3 may be formed on the first to third pixel electrodes AE1, AE2, AE3 exposed by the pixel opening. Specifically, the first intermediate layer ML1 may be formed on the first pixel electrode AE1, the second intermediate layer ML2 may be formed on the second pixel electrode AE2, and the third intermediate layer ML3 may be formed on the third pixel electrode AE3.

In an embodiment, the first to third intermediate layers ML1, ML2, ML3 may be formed through an inkjet printing process. Specifically, the first to third light emitting layers EML1, EML2, EML3 (see in FIGS. 5 and 6) may be formed through an inkjet printing process.

In an embodiment, for example, an organic composition may be provided to the pixel opening exposing the first pixel electrode AE1 through an inkjet printing process. The organic composition may be a material for forming the first emitting layer EML1. That is, the organic composition may include a solvent and the organic light emitting material.

Additionally, a first quantum dot composition may be provided to the pixel opening exposing the second pixel electrode AE2 through an inkjet printing process. The first quantum dot composition may be a material for forming the second light emitting layer EML2. That is, the first quantum dot composition may include a solvent and the inorganic light emitting material including the first quantum dot QD1 (see in FIGS. 5 and 6).

Additionally, a second quantum dot composition may be provided to the pixel opening exposing the third pixel electrode AE3 through an inkjet printing process. The second quantum dot composition may be a material for forming the third light emitting layer EML3. That is, the second quantum dot composition may include a solvent and the inorganic light emitting material including the second quantum dot QD2 (see in FIGS. 5 and 6).

Thereafter, the organic composition, the first quantum dot composition, and the second quantum dot composition may be dried and/or heat treated to form the first emitting layer EML1, the second emitting layer EML2, and the third emitting layer EML3.

The first to third hole transport areas HTA1, HTA2, HTA3 and the first to third electron transport areas ETA1, ETA2, ETA3 described with reference to FIGS. 5 and 6 may be also formed through an inkjet printing process. However, the present invention is not necessarily limited thereto, and the method of forming the first to third hole transport areas HTA1, HTA2, HTA3 and the first to third electron transport areas ETA1, ETA2, ETA3 may be changed in various ways depending on embodiments.

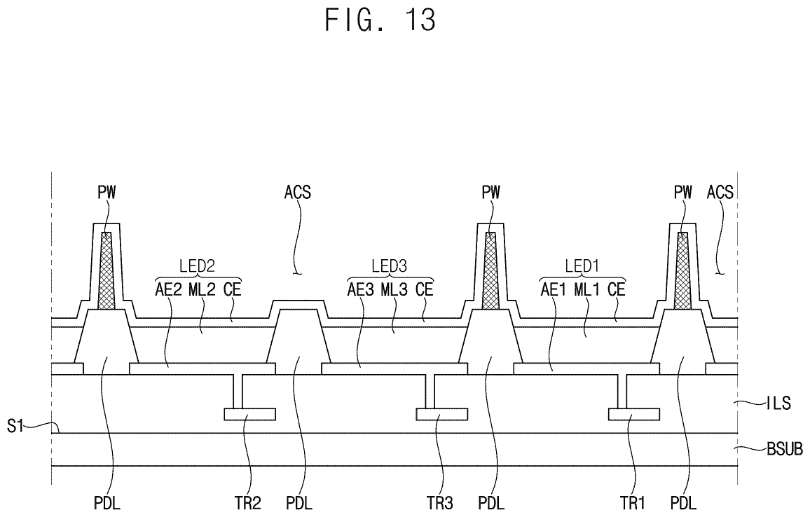

Thereafter, referring to FIG. 13, the common electrode CE may be formed on the first to third intermediate layers ML1, ML2, ML3, the pixel defining layer PDL, and the partition structure PW. Accordingly, the first light emitting element LED1, which includes the first pixel electrode AE1, the first intermediate layer ML1, and the common electrode CE and is an organic light emitting element, may be formed. Additionally, the second light emitting element LED2, which includes the second pixel electrode AE2, the second intermediate layer ML2, and the common electrode CE and is a quantum dot light emitting element may be formed. Additionally, the third light emitting element LED3, which includes the third pixel electrode AE3, the third intermediate layer ML3, and the common electrode CE and is a quantum dot light emitting element, may be formed.

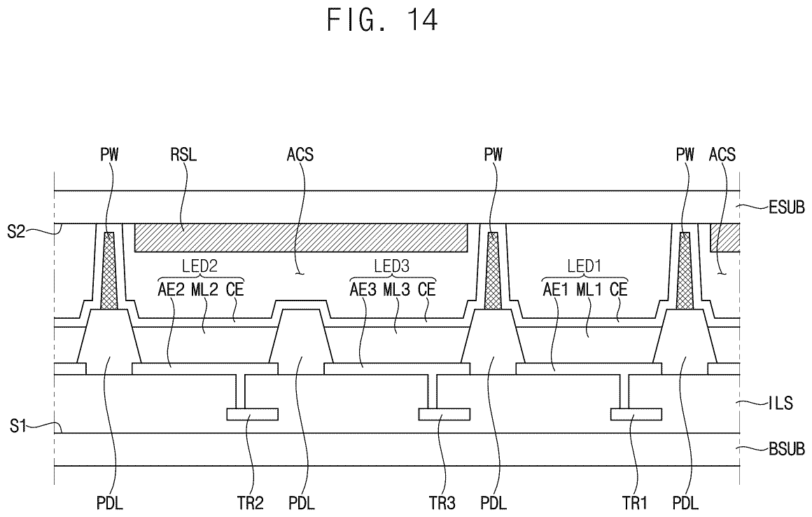

Thereafter, referring to FIG. 14, the first substrate BSUB and the second substrate ESUB may be bonded. Specifically, the first substrate BUSB on which the first to third light emitting elements LED1, LED2, LED3 are formed and the second substrate ESUB on which the resin layer RSL is formed may be bonded. At this time, the first surface S1 of the first substrate BUSB and the second surface S2 of the second substrate ESUB face each other. Accordingly, after the first substrate BSUB and the second substrate ESUB are bonded, the first to third driving elements TR1, TR2, TR3, the insulating structure ILS, the pixel defining layer PDL, the first to third light emitting elements LED1, LED2, LED3, the partition structure PW, and the resin layer RSL may be disposed between the first substrate BSUB and the second substrate ESUB.

The first substrate BSUB and the second substrate ESUB may be bonded such that the resin layer RSL overlaps the second light emitting element LED2 and the third light emitting element LED3 in the plan view, and is spaced apart from the first light emitting element LED1 in the plan view. Specifically, the resin layer RSL is disposed in the accommodation space ACS of the partition structure PW. Accordingly, after the first substrate BUSB and the second substrate ESUB are bonded, at least a portion of the resin layer RSL may be surrounded by the partition structure PW. In an embodiment, for example, the entirety of the resin layer RSL may be surrounded by the partition structure PW.

The first substrate BSUB and the second substrate ESUB may be bonded by the sealing member SM described with reference to FIG. 2. In an embodiment, for example, the first substrate BSUB and the second substrate ESUB may be bonded by applying a laser to the sealing member SM to perform a thermal compression process or by performing a UV irradiation process.

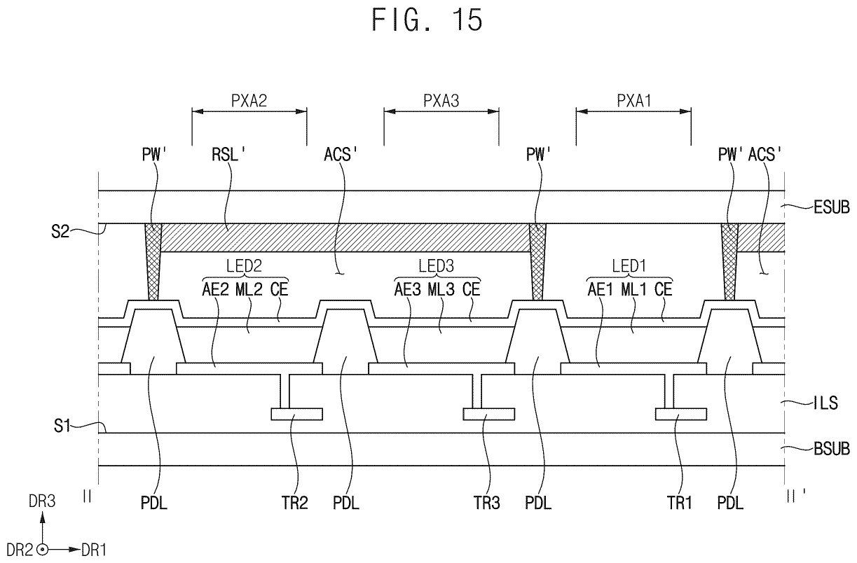

FIG. 15 is a cross-sectional view illustrating another example taken along line II-II′ of FIG. 3.

That is, the cross-sectional view of FIG. 15 may correspond to the cross-sectional view of FIG. 4.

An embodiment of the display device DD described with reference to FIG. 15 may be substantially same as an embodiment of the display device DD described above with reference to FIG. 4 except for the partition structure PW′ and the resin layer RSL′. Additionally, the partition structure PW′ may be substantially the same as the partition structure PW described with reference to FIG. 4 except for an arrangement position. Additionally, the resin layer RSL′ may be substantially the same as the resin layer RSL described with reference to FIG. 4 except for the arrangement form. Therefore, overlapping descriptions are omitted or simplified.

In an embodiment, the partition structure PW′ may be disposed on the common electrode CE. That is, the partition structure PW′ may be disposed between the common electrode CE and the second substrate ESUB. In an embodiment, for example, the partition structure PW′ may be directly disposed on the second surface S2 of the second substrate ESUB. Additionally, the partition structure PW′ may be spaced apart from the pixel defining layer PDL with the common electrode CE interposed therebetween. That is, the partition structure PW′ may not directly contact with (i.e., is spaced apart from) the pixel defining layer PDL.

The partition structure PW′ may define an accommodation space ACS′ like the partition structure PW described with reference to FIG. 4. Since a detailed description of the accommodation space ACS′ is substantially the same as the description of the accommodation space ACS with reference to FIG. 4, it is omitted below.

The resin layer RSL′ may be disposed in the accommodation space ACS′ of the partition structure PW′. In an embodiment, the resin layer RSL′ may be in contact with the partition structure PW′. In an embodiment, for example, the resin layer RSL′ may entirely cover a portion of the second surface S2 of the second substrate ESUB in the accommodation space ACS′ of the partition structure PW′. However, the present invention is not necessarily limited thereto. In an embodiment, for example, the resin layer RSL′ may be spaced apart from (i.e., not directly contact with) the partition structure PW′. For another example, the resin layer RSL′ may be in contact with the partition structure PW′ while exposing a portion of the second surface S2 of the second substrate ESUB in the accommodation space ACS′ of the partition structure PW′.

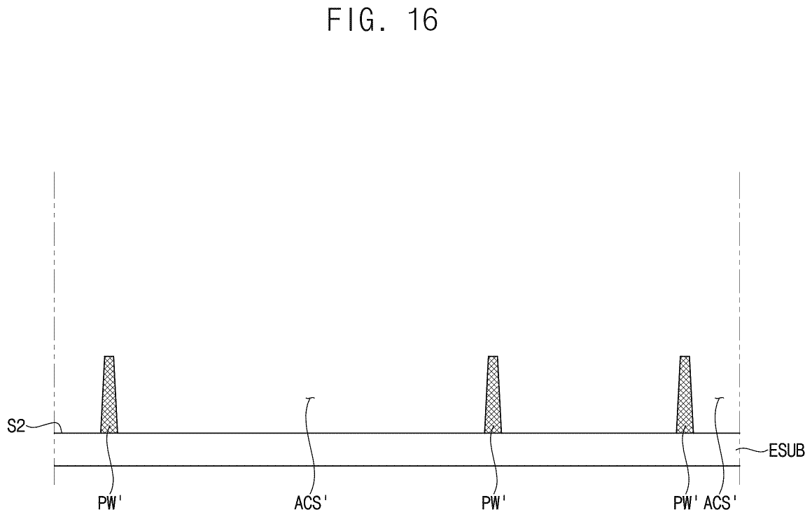

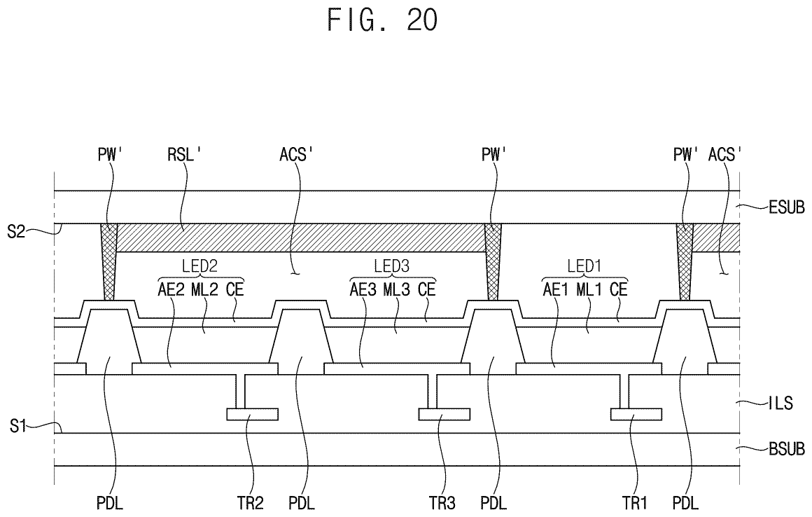

FIGS. 16 to 20 are cross-sectional views illustrating a method of manufacturing a display device according to an embodiment of the present invention.

Specifically, FIGS. 16 to 20 are cross-sectional views for illustrating the manufacturing method of the display device described with reference to FIG. 15.

Referring to FIG. 16, the partition structure PW′ may be formed on the second surface S2 of the second substrate ESUB. The partition structure PW′ may be formed through a process of applying an insulating layer on the second surface S2 of the second substrate ESUB and patterning the insulating layer. The partition structure PW′ may be formed to define the accommodation space ACS′. The accommodation space ACS′ may function as a space for receiving a resin composition discharged by an inkjet printing process to be described later. In an embodiment, the partition structure PW′ may be formed of an organic insulating material.

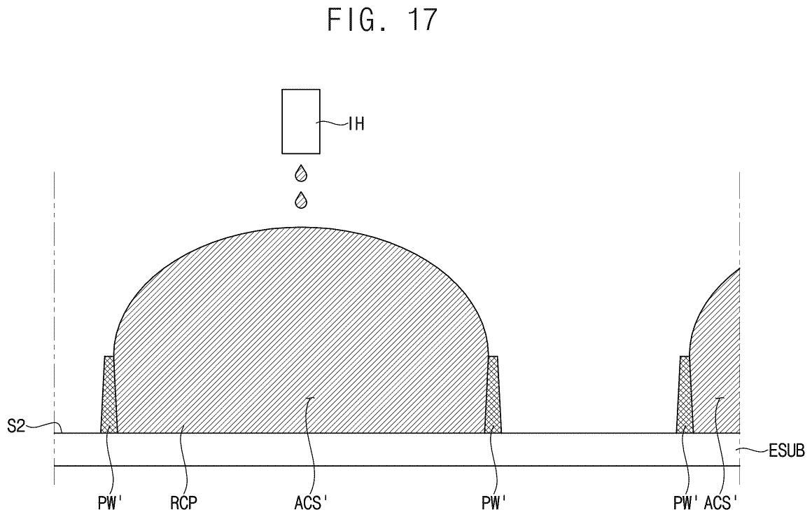

Referring to FIG. 17, a resin composition RCP may be provided in the accommodation space ACS′ of the partition structure PW′. In an embodiment, for example, the resin composition RCP may be provided to the accommodation space ACS′ by an inkjet printing process. That is, the resin composition RCP may be discharged into the accommodation space ACS′ by an inkjet head IH.

The resin composition RCP may be a material for forming the resin layer RSL′ of FIG. 15. In an embodiment, for example, the resin composition RCP may include the resin, a solvent, and the active ingredient.

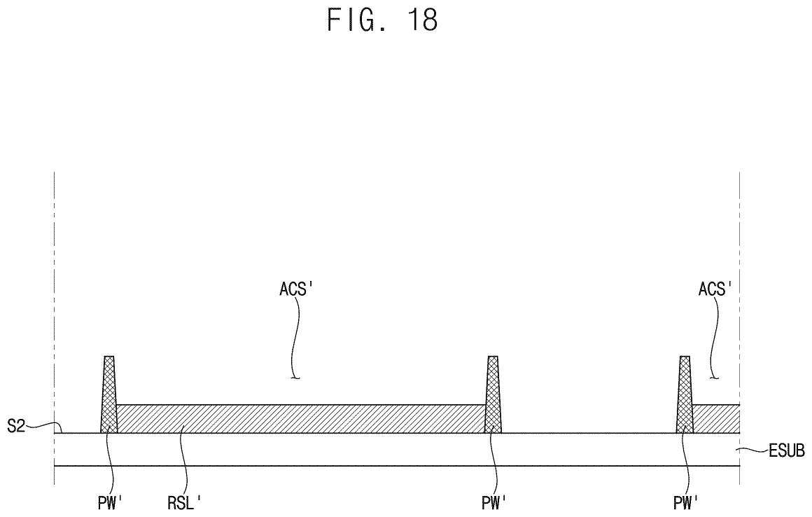

Referring further to FIG. 18, the resin composition RCP may be dried and/or heat treated to form the resin layer RSL′. Therefore, the resin layer RSL′ may include the active ingredient. As a result, the resin layer RSL′ may be formed in the accommodation space ACS′. That is, the resin layer RSL′ may be formed on the second surface S2 of the second substrate ESUB and may be formed to be surrounded by the partition structure PW′.

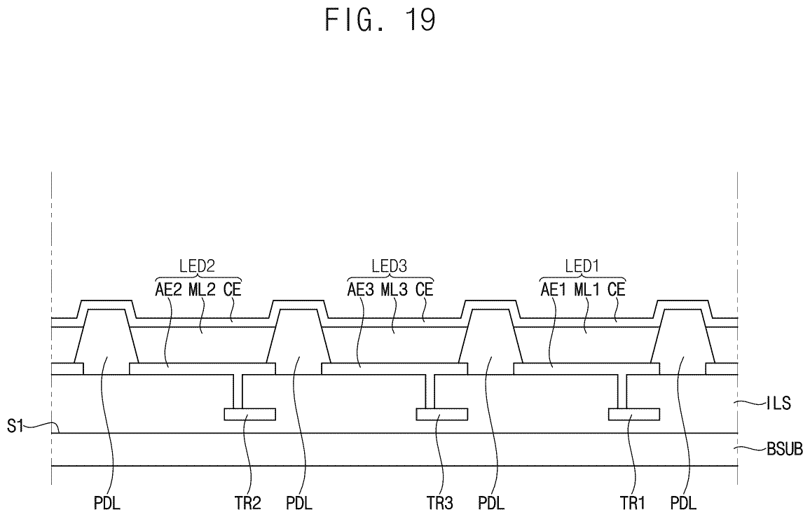

Referring to FIG. 19, the first to third driving elements TR1, TR2, TR3, the insulating structure ILS, and the first to third pixel electrodes AE1, AE2, AE3, the pixel defining layer PDL, the first to third intermediate layers ML1, ML2, ML3, and the common electrode CE may be formed on the first surface S1 of the first substrate BSUB. That is, the first to third light emitting elements LED1, LED2, LED3 may be formed on the first surface S1 of the first substrate BSUB.

A method of forming the first to third driving elements TR1, TR2, TR3, the insulating structure ILS, the first to third pixel electrodes AE1, AE2, AE3, the pixel defining layer PDL, the intermediate layers ML1, ML2, ML3 and the common electrode CE may be substantially the same as the description with reference to FIGS. 10 and 13. Therefore, detailed description is omitted.

Thereafter, referring to FIG. 19, the first substrate BSUB and the second substrate ESUB may be bonded. Specifically, the first substrate BUSB on which the first to third light emitting elements LED1, LED2, LED3 are formed and the second substrate ESUB on which the resin layer RSL′ is formed may be bonded. At this time, the first surface S1 of the first substrate BUSB and the second surface S2 of the second substrate ESUB face each other. Accordingly, after the first substrate BSUB and the second substrate ESUB are bonded, the first to third driving elements TR1, TR2, TR3, the insulating structure ILS, the pixel defining layer PDL, the first to third light emitting elements LED1, LED2, LED3, the partition structure PW′, and the resin layer RSL′ may be disposed between the first substrate BSUB and the second substrate ESUB.

The first substrate BSUB and the second substrate ESUB may be bonded such that the resin layer RSL′ overlaps the second light emitting element LED2 and the third light emitting element LED3 in the plan view, and is spaced apart from the first light emitting element LED1 in the plan view. Specifically, the first substrate BUSB and the second substrate ESUB may be bonded such that the accommodation space ACS′ of the partition structure PW′ overlaps the second light emitting element LED2 and the third light emitting device LED3 in the plan view, and is spaced apart from the first light emitting element LED1 in the plan view.

The first substrate BSUB and the second substrate ESUB may be bonded by the sealing member SM described with reference to FIG. 2. In an embodiment, for example, the first substrate BSUB and the second substrate ESUB may be bonded by applying a laser to the sealing member SM to perform a thermal compression process or by performing a UV irradiation process.

The display device DD according to embodiments of the present invention may be a display device with a hybrid structure that includes both an organic light emitting element and a quantum dot light emitting element. Additionally, the display device DD may include a resin layer containing an active ingredient. The active ingredient may promote a positive aging effect of the quantum dot light emitting element. On the other hand, when the active ingredient diffuses into the organic light emitting element, element characteristics may deteriorate, unlike the quantum dot light emitting element.

According to embodiments, the resin layer may selectively overlap the quantum dot light emitting element in a plan view, and may be spaced apart from the organic light emitting element in the plan view. Therefore, the active ingredient may selectively diffuse into the quantum dot light emitting element from the resin layer. That is, the active ingredient may not affect the organic light emitting element.

Additionally, the display device DD may further include a partition structure surrounding at least a portion of the resin layer. Accordingly, the active ingredient diffusing from the resin layer may be blocked from diffusing into a specific path by the partition structure. For example, the active ingredient may not reach the organic light emitting element due to the partition structure. Therefore, the active ingredient may not affect the organic light emitting element.

As a result, in the display device DD according to embodiments of the present invention, the active ingredient may be selectively diffused into the quantum dot light emitting element by the resin layer and the partition structure. That is, the active ingredient may not affect the organic light emitting element. Therefore, it is possible to promote the positive aging effect of the quantum dot light emitting element and at the same time prevent or reduce a deterioration of element characteristics of the organic light emitting element. Accordingly, element characteristics of the display device DD may be effectively improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first light emitting element disposed on a first surface of a first substrate and including a first light emitting layer including an organic light emitting material;
a second light emitting element disposed on the first surface of the first substrate and including a second light emitting layer including an inorganic light emitting material;
a second substrate facing the first surface of the first substrate and disposed on the first light emitting element and the second light emitting element; and
a resin layer disposed on a second surface of the second substrate facing the first surface of the first substrate, including an active ingredient, spaced apart from the first light emitting element in a plan view, and overlapping the second light emitting element in the plan view.

2. The display device of claim 1, further comprising:
a partition structure disposed between the first substrate and the second substrate and surrounding at least a portion of the resin layer.

3. The display device of claim 2, further comprising:
a pixel defining layer disposed on the first surface of the first substrate to surround the first light emitting layer and the second light emitting layer, and
wherein the partition structure is disposed on the pixel defining layer.

4. The display device of claim 2, wherein at least a portion of the partition structure is disposed between the first light emitting element and the second light emitting element in the plan view.

5. The display device of claim 1, wherein the second light emitting element includes the active ingredient.

6. The display device of claim 1, wherein the active ingredient included in the resin layer includes an acid.

7. The display device of claim 1, wherein the inorganic light emitting material includes a quantum dot.

8. The display device of claim 1, wherein a color of light emitted by the first light emitting element is different from a color of light emitted by the second light emitting element.

9. The display device of claim 1, further comprising:
a common electrode on the first light emitting layer and the second light emitting layer, and
wherein the resin layer is spaced apart from the common electrode.

10. The display device of claim 1, wherein the second substrate is spaced apart from the first substrate, the first light emitting element, and the second light emitting element.

11. A method of manufacturing a display device, the method comprising:
forming a first light emitting element and a second light emitting element on a first surface of a first substrate, wherein the first light emitting element includes a first light emitting layer including an organic light emitting material, and the second light emitting element includes a second light emitting layer including an inorganic light emitting material;
forming a resin layer including an active ingredient on a second surface of a second substrate; and
bonding the second substrate, on which the resin layer is formed, and the first substrate, on which the first light emitting element and the second light emitting element are formed, such that the resin layer is spaced apart from the first light emitting element and overlaps the second light emitting element in a plan view.

12. The method of claim 11, wherein after the bonding of the first substrate and the second substrate, the first surface of the first substrate and the second surface of the second substrate face each other, and
the resin layer is disposed between the first substrate and the second substrate after the bonding of the first substrate and the second substrate.

13. The method of claim 11, wherein the second light emitting layer is formed of a quantum dot composition.

14. The method of claim 11, wherein the first light emitting element and the second light emitting element are formed to emit light of different colors from each other.

15. The method of claim 11, wherein the active ingredient includes an acid.

16. The method of claim 11, wherein the forming of the resin layer on the second substrate includes:
forming a preliminary resin layer including the active ingredient on the second surface of the second substrate;
forming a photoresist pattern on the preliminary resin layer; and
removing a portion of the preliminary resin layer using the photoresist pattern as a mask to form the resin layer.

17. The method of claim 16, further comprising:
forming a partition structure defining an accommodation space on the first surface of the first substrate, and
wherein the forming of the partition structure is performed before the bonding the first substrate and the second substrate.

18. The method of claim 17, wherein after the bonding of the first substrate and the second substrate, the partition structure is disposed between the first substrate and the second substrate, and the resin layer is disposed in the accommodation space.

19. The method of claim 11, wherein the forming of the resin layer on the second substrate includes:
forming a partition structure defining an accommodation space on the second surface of the second substrate;
discharging a resin composition including the active ingredient into the accommodation space of the partition structure; and
drying the resin composition to form the resin layer in the accommodation space.

20. The method of claim 19, wherein after the bonding of the first substrate and the second substrate,
the partition structure is disposed between the first substrate and the second substrate.
